(19) United States
(12) Patent Application Publication
(10) Pub. No.: US 2012/0216868 A1
(43) Pub. Date: Aug. 30, 2012

(54) MANUFACTURING METHOD OF ORGANIC PHOTOVOLTAIC CELL

(76) Inventors: Takahiro Seike, Ibaraki (JP); Toshihiro Ohnishi, Ibaraki (JP)

(21) Appl. No.: 13/504,733

(22) PCT Filed: Oct. 22, 2010
(86) PCT No.: PCT/JP2010/068732

§ 371 Date: Apr. 27, 2012

(30) Foreign Application Priority Data
Oct. 30, 2009 (JP) 2009-251248

(51) Int. Cl. H01L 51/44; H01L 51/48; H01L 31/18

(52) U.S. Cl. 136/263; 438/98; 257/E31.124

(57) ABSTRACT

A method of manufacturing an organic photovoltaic cell is provided that prevents organic layer deterioration during manufacture, wherein the organic photovoltaic cell contains: a pair of electrodes including a first electrode provided on a first substrate and a second electrode provided on a second substrate; and an active layer placed between the pair of electrodes. The method includes: forming a first electrical charge transport layer on the first electrode; forming a first layered structure body by forming an active layer on the first electrical charge transport layer; forming a second layered structure body by forming a second electrical charge transport layer on the second electrode; and joining the first layered structure body and the second layered structure body by bringing the active layer provided on the first layered structure body and the second electrical charge transport layer provided on the second layered structure body into contact with each other.

### TECHNICAL FIELD

The present invention relates to a method for manufacturing an organic photovoltaic cell and an organic photovoltaic cell that can be obtained by the manufacturing method.

### BACKGROUND ART

An organic photovoltaic cell is usually manufactured by performing the following steps in order: (1) a step that a first electrode is formed on a substrate; (2) a step that a first electrical charge transport layer is formed on the first electrode; (3) a step that an active layer is formed on the first electrical charge transport layer; (4)a step that a second electrical charge transport layer is formed on the active layer; and (5) a step that a second electrode is formed on the second electrical charge transport layer.

An organic photovoltaic cell has a layer comprising an organic compound (the layer may be also called “organic layer”) as an essential component such as an active layer, an electron-acceptor layer and an electron-donor layer. An organic layer tends to be easily deteriorated due to oxygen and the like in an external environment, and it is known that after the step of forming an organic layer, especially in a step performed under a high temperature such as an electrode forming step, deterioration or loss of function of an organic layer may be caused.

For reducing deterioration of an organic layer caused by a manufacturing process of the cell, a manufacturing method of an organic photovoltaic cell is known, in which a structural body of a glass substrate vaporized with gold (Au) is stacked with a structural body comprising a TiO₂ film and a P3HT/PCBM mixed film in this order on a glass substrate provided with an ITO electrode (see Non Patent Literature 1).

### RELATED ART DOCUMENTS

Non Patent Literature 1: Solar Energy Materials and Solar Cells, Vol. 93 (2009) pp. 1681-1684

### DISCLOSURE OF INVENTION

### Problem to be Solved by the Invention

However, according to the conventional method of the related art document, the structural body of a glass substrate vaporized with gold as an electrode is placed in contacted with the structural body in which an ITO electrode, a TiO₂ film, and a P3HT/PCBM mixed film as an active layer are provided on a glass substrate in this order, so that the gold and the active layer are brought into contacted with each other under a heat condition of 100° C. to 150° C., and thus an organic photovoltaic cell is manufactured. Therefore, the conventional manufacturing method still causes deterioration of an organic layer due to a high temperature during a manufacturing process, and further causes a reduction in the photovoltaic conversion efficiency and a loss of function in some cases.

The inventors of the present invention have studied intensively a method for manufacturing an organic photovoltaic cell. As a result, they have found that the abovementioned problem can be solved by, forming a structural body as a separate one which is a component requiring a heat treatment and then joining to a structural body provided with an organic layer such as an active layer that is easily affected by a high temperature, and thereby the present inventors have completed the present invention.

Therefore, the present invention provides the following method for manufacturing an organic photovoltaic cell and the organic photovoltaic cell.

[1] A method for manufacturing an organic photovoltaic cell comprising a first substrate, a second substrate, a pair of electrodes of a first electrode provided on the first substrate and a second electrode provided on the second substrate, and an active layer placed between the pair of electrodes, the manufacturing method comprising the steps of:

forming a first electrical charge transport layer on the first electrode provided on the first substrate;

forming a first layered structure body by forming the active layer on the first electrical charge transport layer;

forming a second layered structure body by forming a second electrical charge transport layer on the second electrode provided on the second substrate; and

joining the first layered structure body and the second layered structure body by bringing the active layer provided on the first layered structure body and the second electrical charge transport layer provided on the second layered structure body into contact with each other.

[2] A method for manufacturing an organic photovoltaic cell comprising a first substrate, a second substrate, a pair of electrodes of a first electrode provided on the first substrate and a second electrode provided on the second substrate, and an active layer placed between the pair of electrodes, the manufacturing method comprising the steps of:

forming a first electrical charge transport layer on the first electrode provided on the first substrate;

forming a first layered structure body by forming a first electrically conductive layer on the first electrical charge transport layer;

forming a second layered structure body, by forming a second electrical charge transport layer on the second electrode provided on the second substrate and forming a second electrically conductive layer on the second electrical charge transport layer; and

joining the first electrically conductive layer and the second electrically conductive layer, by bringing the first electrically conductive layer and the second electrically conductive layer into contact with each other and joining them to form the active layer in which the first electrically conductive layer and the second electrically conductive layer are stacked.

[3] The method for manufacturing an organic photovoltaic cell according to [1] or [2], wherein, in the joining step, either one or both of the first substrate and the second substrate is pressurized.
[4] The method for manufacturing an organic photovoltaic cell according to any one of [1] to [3], wherein the joining step is performed under a temperature higher than an ordinary temperature.
[5] The method for manufacturing an organic photovoltaic cell according to claim [4], wherein the joining step is performed under a temperature higher than 40° C. and lower than 100° C.
[6] The method for manufacturing an organic photovoltaic cell according to any one of [1] to [5], wherein the joining step is performed in an atmosphere of solvent vapor that dissolves a surface of either one or both of: an exposed layer that is included in the first layered structure body and exists at an opposite side to the first substrate; and an exposed layer that is included in the second layered structure and exists at an opposite side to the second substrate.
[7] The method for manufacturing an organic photovoltaic cell according to [6], wherein an aromatic hydrocarbon vapor or an aliphatic hydrocarbon vapor is used as the solvent vapor.
[8] The method for manufacturing an organic photovoltaic cell according to [6], wherein water vapor or an alcohol vapor is used as the solvent vapor.
[9] The method for manufacturing an organic photovoltaic cell according to any one of [1] to [8], after the joining step, further comprising a step of performing a vacuum treatment in a vacuum to the first layered structure body and the second layered structure body that are joined to each other.
[10] The method for manufacturing an organic photovoltaic cell according to any one of [6] to [9], wherein, in the joining step, either one or both of the exposed layer that is included in the first layered structure body and exists at the opposite side to the first substrate and the exposed layer that is included in the second layered structure body and exists at the opposite side to the second substrate is a layer comprising an organic compound.
[11] The method for manufacturing an organic photovoltaic cell according to any one of [6] to [9], wherein, in the joining step, either one or both of the exposed layer that is included in the first layered structure body and exists at the opposite side to the first substrate and the exposed layer that is included in the second layered structure body and exists at the at the opposite side to the second substrate is a layer comprising an inorganic compound.
[12] An organic photovoltaic cell manufactured by the manufacturing method according to any one of [1] to [11].
[13] The organic photovoltaic cell according to [12], wherein a distance between the primary surface of the first substrate and the primary surface of the second substrate, which face each other, is larger than 300 nm and smaller than 500 nm.
[14] The organic photovoltaic cell according to [12] or [13], wherein the substrate of either one or both of the first substrate and the second substrate is an inorganic compound film.
[15] The organic photovoltaic cell according to [12] or [13], wherein the substrate of either one or both of the first substrate and the second substrate is an organic compound film.
[16] The organic photovoltaic cell according to [14], wherein the inorganic compound film is made of a metal or an alloy.
[17] The organic photovoltaic cell according to [15], wherein the organic compound film further comprises a barrier layer.

### BRIEF DESCRIPTION OF DRAWINGS

FIG. 1 is a schematic cross sectional view (1) illustrating a method for manufacturing an organic photovoltaic cell.

FIG. 2 is a schematic cross sectional view (2) illustrating a method for manufacturing an organic photovoltaic cell.

FIG. 3 is a schematic cross sectional view (3) illustrating a method for manufacturing an organic photovoltaic cell.

FIG. 4 is a schematic cross sectional view (1) illustrating a structure of an organic photovoltaic cell.

FIG. 5 is a schematic cross sectional view (2) illustrating a structure of an organic photovoltaic cell.

### EXPLANATIONS OF LETTERS OR NUMERALS

10 organic photovoltaic cell
10A first layered structure body
10B second layered structure body
20A first substrate
20B second substrate
32 first electrode
34 second electrode
42 first electrical charge transport layer
44 second electrical charge transport layer
50 active layer
52 first electrically conductive layer
54 second electrically conductive layer

### DESCRIPTION OF EMBODIMENTS

### <Manufacturing Method of Organic Photovoltaic Cell>

Hereafter, the present invention is described in detail referring to Figures. In the following description, respective Figures illustrate only an outline of a shape, a size, and an arrangement to the extent that the present invention is understood, and therefore the present invention is not limited to those. In addition, respective Figures have the same letters or numbers with respect to the same components, and repeating descriptions may be omitted.

An organic photovoltaic cell manufactured by the manufacturing method of the present invention has a pair of electrodes one of which is a first electrode provided on a first substrate and the other of which is a second electrode provided on a second substrate and an active layer placed between the pair of electrodes.

### First Embodiment

The manufacturing method of an organic photovoltaic cell of a first embodiment comprises a step of forming a first electrical charge transport layer on a first electrode provided on a first substrate, a step of forming a first layered structure body by forming an active layer on the first electrical charge transport layer, a step of forming a second layered structure body by forming a second electrical charge transport layer on a second electrode provided on a second substrate, and a step of joining the first layered structure body with the second layered structure body by bringing the active layer of the first layered structure body with the second electrical charge transport layer of the second layered structure body into contact with each other.

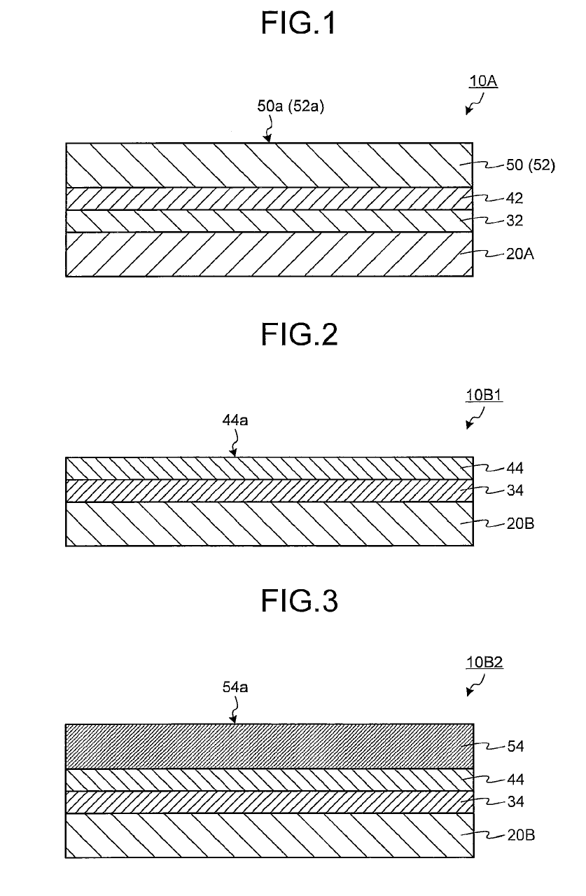

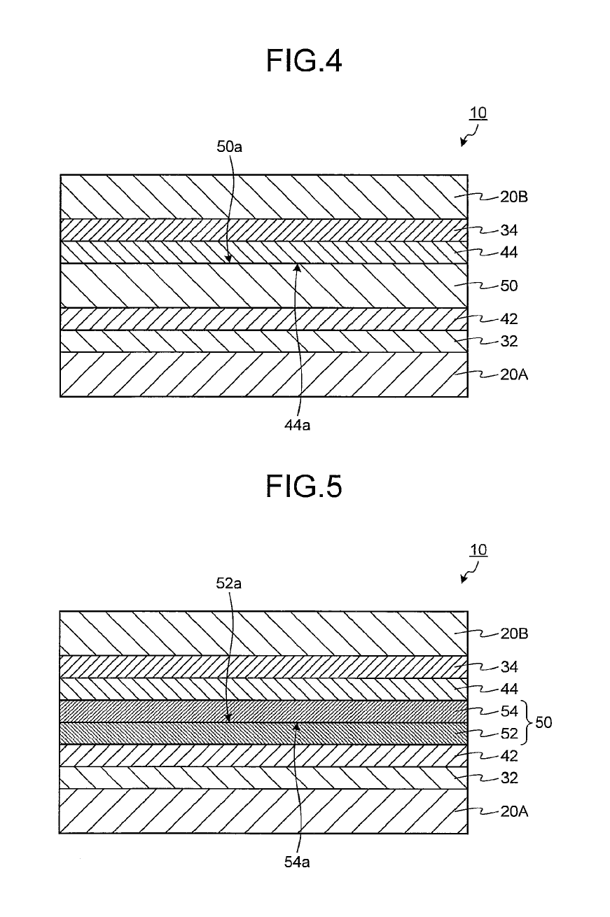

The manufacturing method of an organic photovoltaic cell of the first embodiment is described in detail referring to FIG. 1, FIG. 2, and FIG. 4.

FIG. 1 is a schematic cross sectional view 1 of a manufacturing method of an organic photovoltaic cell. FIG. 2 is a schematic cross sectional view 2 of a manufacturing method of an organic photovoltaic cell. FIG. 4 is a schematic cross sectional view 1 of composition of an organic photovoltaic cell.

As illustrated in FIG. 1, firstly, a first layered structure body 10A is prepared. For preparing the first layered structure body 10A, a first substrate 20A is prepared. The first substrate 20A is a flat-plate substrate that has two primary surfaces facing each other. As the first substrate 20A, a substrate may be prepared so that one of the primary surfaces of the first substrate 20A is previously provided with a thin film made of an electrically conductive material capable of being a material for an electrode, for example, indium tin oxide (also called ITO).

The material for the first substrate 20A may be anything as long as the one that can be provided with an electrode and will not be changed chemically during forming a layer comprising an organic substance. The first substrate 20A is preferably: an inorganic compound film made from a metal such as aluminum, copper, silver and titanium, or from an alloy such as stainless steel, or from a material comprising an oxides such as glass; and an organic compound film made from such as polyethylene telephthalate, polyethylene naphthalate, and polyimide which may have a barrier layer such as silicon oxide or silicon nitride.

Examples of a material for the first substrate 20A may include a glass, a plastic, a macromolecule film, and silicon.

When the first substrate 20A is not provided with a thin film of an electrically conductive material, a thin film of an electrically conductive material is formed on one of primary surfaces of the first substrate 20A by using arbitrarily an appropriate method such as evaporation. Next, the thin film of an electrically conductive material is patterned. The thin film of an electrically conductive material is patterned by using arbitrarily an appropriate method such as photolithography process and etching process, and thereby a first electrode 32 is formed.

Between the first electrode 32 and the second electrode 34 described below, at least one electrode being at a side from which light enters is a transparent or translucent electrode through which incident light (solar light) having a required wavelength for power generation can permeate.

When the first substrate 20A is non-transparent and therefore does not allow incident light to permeate, a second substrate 20B and second electrode 32, which are opposed to the first electrode 32 and thus are provided at an opposite side to the first substrate 20A, is required to be transparent or to be translucent for allowing incident light to permeate.

The polarity of the first electrode 32 and the second electrode 34 may be selected arbitrarily an appropriate polarity for an cell structure, and therefore the first electrode 32 may be a cathode and the second electrode 34 may be an anode.

Examples of a transparent electrode or a translucent electrode may include an electrically conductive metallic oxide film and a translucent metal thin film. For transparent or translucent electrodes, for example, a film prepared from an electrically conductive material of indium oxide, zinc oxide, tin oxide, or a complex thereof such as indium tin oxide and indium zinc oxide (IZO); and a film of NESA and the like, gold, platinum, silver, copper or the like, are used. Preferably, a film of ITO, IZO, or tin oxide are used.

Examples of a preparation method of an electrode may include vacuum evaporation, sputtering, ion plating, plating, and the like. In addition, as an electrode, an organic transparent electro conductive film prepared from polyaniline or a derivative thereof, polythiophene or a derivative thereof or the like may be used.

As an electrode material for the non-transparent electrode, a metal, an electrically conductive macromolecule and the like may be used. Examples of an electrode material for the non-transparent electrode may include: a metal such as lithium, sodium, potassium, rubidium, cesium, magnesium, calcium, strontium, barium, aluminum, scandium, vanadium, zinc, yttrium, indium, cerium, samarium, europium, terbium, and ytterbium; an alloy of two or more of these metals; an alloy of one or more types of the above metals and one or more types of metals selected from a group of gold, silver, platinum, copper, manganese, titanium, cobalt, nickel, tungsten, and tin; a graphite; a graphite intercalation compound; polyaniline and a derivative thereof; and polythiophene and a derivative thereof. Examples of an alloy may include magnesium-silver alloy, magnesium-indium alloy, magnesium-aluminum alloy, indium-silver alloy, lithium-aluminum alloy, lithium-magnesium alloy, lithium-indium alloy, and calcium-aluminum alloy.

Next, a first electrical charge transport layer 42 is prepared on the first substrate 20A provided with the first electrode 32.

The first electrical charge transport layer 42 is a hole transport layer when the first electrode 32 is an anode, or is an electron transport layer when the first electrode 32 is a cathode.

Examples of a material usable for the first electrical charge transport layer 42 may include a halogenated compound of an alkali earth metal or an alkaline metal such as lithium fluoride, an oxide of an alkaline metal or an alkali earth metal. Also, inorganic semiconductor particulates such as titanium oxide, PEDOT (poly-3,4-ethylenedioxythiophene) and the like are included.

When the first electrical charge transport layer 42 is an electron transport layer, an example of the material is 2,9-dimethyl-4,7-diphenyl-1,10-phenanthrolin (BCP). When the first electrical charge transport layer 42 is a hole transport layer, an example of the material is PEDOT.

Then, an active layer 50 that covers the first electrical charge transport layer 42 is formed. In this embodiment, the active layer 50 is a bulk hetero organic layer in which an electron-acceptor compound (an n-type semiconductor material) and an electron-donor compound (a p-type semiconductor material) are mixed to be contained, and is a layer having a substantial function for photovoltaic function capable of generating electrical charges (hole and electron) by utilizing energy of incident light.

The active layer 50, as described above, comprising an electron-donor compound and electron-acceptor compound.

Here, electron-donor compound and electron-acceptor compound are determined relatively according to the energy level of an energy level of these compounds. One compound may be either of an electron-donor compound or electron-acceptor compound.

Examples of an electron-donor compound may include a pyrazoline derivative, an arylamine derivative, a stilbene derivative, a triphenyl diamine derivative, oligothiophene and a derivative thereof, polyvinyl carbazole and a derivative thereof, polysilane and a derivative thereof, a polysiloxane derivative having an aromatic amine at the side chain or the main chain, polyaniline and a derivative thereof, polythiophene and a derivative thereof, polypyrrole and a derivative thereof, polyphenylene vinylene and a derivative thereof, polythienylene vinylene and a derivative thereof.

Examples of an electron-acceptor compound may include an oxadiazole derivative, anthraquinodimethane and a derivative thereof, benzoquinone and a derivative thereof, naphthoquinone and a derivative thereof, anthraquinone and a derivative thereof, tetracyanoanthraquinodimethane and a derivative thereof, a fluorenone derivative, diphenyl dicyanoethylene and a derivative thereof, a diphenoquinone derivative, 8-hydroxyquinoline and a metal complex of its derivative, polyquinoline and a derivative thereof, polyquinoxaline and a derivative thereof, polyfluorene and a derivative thereof, a fullerene such as C₆₀ fullerene and a derivative thereof, a phenanthrene derivative such as bathocuproin, a metallic oxide such as titanium oxide, and a carbon nanotube. As an electron-acceptor compound, preferably, titanium oxide, a carbon nanotube, a fullerene and a fullerene derivative are included, and more preferably, a fullerene, and a fullerene derivative are included.

Examples of a fullerene may include C₆₀ fullerene, C₇₀ fullerene, C₇₆ fullerene, C₇₈ fullerene, and C₈₄ fullerene.

As examples of a fullerene derivative, respective derivatives of C₆₀ fullerene, C₇₀ fullerene, C₇₆ fullerene, C₇₈ fullerene and C₈₄ fullerene are included. Examples of a specific structure of a fullerene derivative may include the following structures.

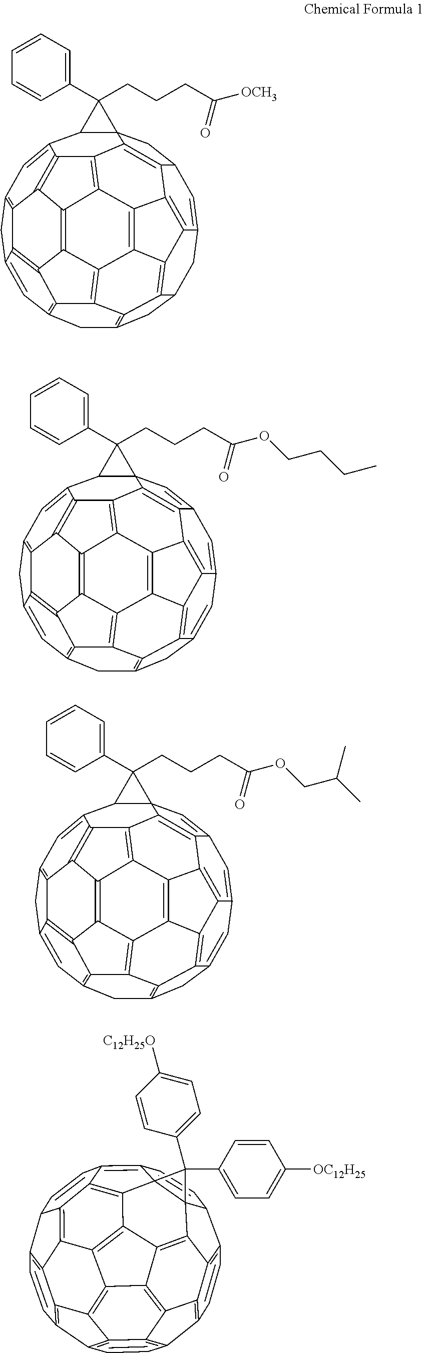

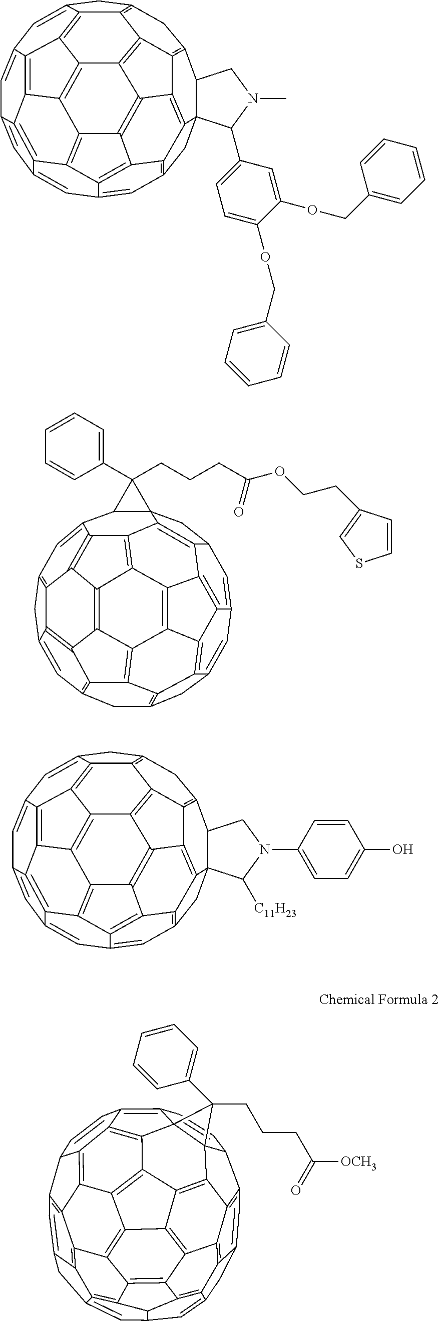

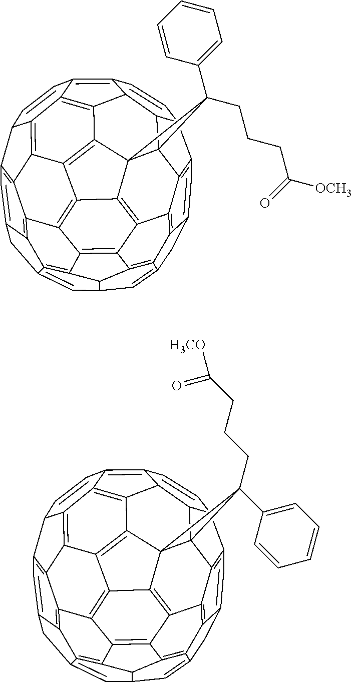

Examples of a fullerene derivative may include

[6,6]phenyl-C₆₁ butyric acid methyl ester (C₆₀ PCBM),
[6,6]phenyl-C₇₁ butyric acid methyl ester (C₇₀ PCBM),
[6,6]phenyl-C₈₅ butyric acid methyl ester (C₈₄ PCBM), and
[6,6]thienyl-C₅₁ butyric acid methyl ester.

When a fullerene derivative is used as an electron-acceptor compound, the proportion of a fullerene derivative is preferably 10 to 1000 parts by weight, more preferably 20 to 500 parts by weight, per 100 parts by weight of an electron-donor compound.

Usually, thickness of an active layer is preferably 1 nm to 100 μm, more preferably 2 nm to 1000 nm, and further preferably 5 nm to 500 nm, and still further preferably 20 nm to 200 nm.

The first electrical charge transport layer 42 and the active layer 50 may be formed by using a film formation method in which a layer formed by coating using a coating fluid, i.e., a solution, is dried under a condition appropriate for both the materials and the solvent in an arbitrarily selected and appropriate atmosphere such as in a nitrogen gas atmosphere.

As a film formation method, a coating method such as spin coating, casting, micro gravure coating, gravure coating, bar coating, roll coating, wire bar coating, dip coating, spray coating, screen printing, gravure printing, flexo printing, offset printing, inkjet printing, dispenser printing, nozzle coating, and capillary coating may be used, and spin coating, flexo printing, gravure printing, inkjet printing, and dispenser printing are preferred.

A solvent used in a film formation method is not limited as long as the solvent dissolve a material for each of layers.

Examples for such the solvent may include an unsaturated hydrocarbon solvent such as toluene, xylene, mesitylene, tetralin, decalin, bicyclohexyl, butylbenzene, sec-butylbenzene, tert-butylbenzene; a halogenated saturated hydrocarbon solvent such as carbon tetrachloride, chloroform, dichloromethane, dichloroethane, chlorobutane, bromobutane, chloropentane, bromopentane, chlorohexane, bromohexane, chlorocyclohexane, and bromocyclohexane; a halogenated unsaturated hydrocarbon solvent such as chlorobenzene, dichlorobenzene, trichlorobenzene; an ether solvent such as tetrahydrofuran, and tetrahydropyran.

Through the steps described above, the first layered structure body 10A is manufactured, which is provided with the first substrate 20A, the first electrode 32 provided on the first substrate 20A, the first electrical charge transport layer 42 provided on the first electrode 32, and the active layer 50 provided on the first electrical charge transport layer 42.

As illustrated in FIG. 2, a second layered structure body 10B1 is manufactured through steps different from the above steps for manufacturing the first layered structure body 10A. First, the second electrode 34 is formed on one of the primary surfaces of the second substrate 20B.

Next, the second electrical charge transport layer 44 is formed on the second substrate 20B provided with the second electrode 34.

The second electrical charge transport layer 44 is a hole transport layer when the second electrode 34 is an anode, and is an electron transport layer when the second electrode 34 is a cathode.

A material for the second substrate 20B, the second electrode 34, and the second electrical charge transport layer 44 may be selected depending on the first substrate 20A, the first electrode 32, and the first electrical charge transport layer 42 of the first layered structure body 10A. With regard to the manufacturing step, the step of manufacturing the second electrode 34 is similar to the step of manufacturing the first electrode 32, and the step of manufacturing the second electrical charge transport layer 44 is similar to the step of manufacturing the first electrical charge transport layer 42.

Through the above steps, the second layered structure body 10B1 of the first embodiment is manufactured, which is provided with the second substrate 20B, the second electrode 34 provided on the second substrate 20B, and the second electrical charge transport layer 44 provided on the second electrode 34.

As illustrated in FIG. 4, the first layered structure body 10A and the second layered structure body 10B1 are brought into contact with each other, and are joined (see FIG. 1 and FIG. 2). In the present example, the surface 50a of the active layer 50, which is an exposed layer of the first layered structure body 10A and exists at the opposite side to the first substrate 20A, is brought into contact and joined with a surface 44a of the second electrical charge transport layer 44 which is an exposed layer of the second layered structure body 10B1 and exists at the opposite side to the second substrate 20B.

A joining step is performed by, for example, a pressurizing step in which either one or both of the first substrate 20A and the second substrate 20B is pressed.

In the pressurizing step, the first layered structure body 10A and the second layered structure body 10B1 may be joined so as to be unified: for example, a pressure is applied from a side of an exposed primary surface of either one or both of the first substrate 20A and the second substrate 20B by using a well known pressurizing device equipped with a pressurizing surface plate such as a device used in a joining step of a manufacturing process of a liquid crystal display panel. With regard to the degree of pressure, under a condition that a layer structure will not be destroyed and a stable joining intensity will be ensured, any appropriate pressure may be adopted to perform the pressurizing step.

The joining step is preferably performed under a temperature higher than an ordinary temperature (around 25° C.) that is not particularly adjusted. The temperature may be any appropriate temperature taking into consideration heat resistance of a material for an organic photovoltaic cell to be manufactured and the appropriate temperature for joining.

The temperature higher than an ordinary temperature is, for example, higher than 40° C. and lower than 100° C.

By performing a joining step under a temperature higher than an ordinary temperature, joining can be made stronger.

In addition, the joining step is preferably performed in an atmosphere of solvent vapor so as to solve the surface of either one or both of an exposed layer that is included in the first layered structure body and exists at the opposite side to the first substrate or an exposed layer that is included in the second layered structure body and exists at the opposite side to the second substrate.

The solvent vapor may be arbitrarily decided as an appropriate solvent vapor for a material of the exposed layer. As a material for the solvent vapor, when an exposed layer is an active layer, preferably an aromatic hydrocarbon compound such as chloroform, toluene, xylen, and chlorobenzene may be used, and when the material for the exposed layer is an water soluble material such as PEDOT:PSS, preferably, water, and an alcohol such as methanol, ethanol and isopropyl alcohol, or a mixture thereof may be used.

By performing the joining step in a state that the surface of the exposed layer which is a joining surface is dissolved, affinity between the layers can be increased and further joining strength can be made stronger.

According to a method for manufacturing an organic photovoltaic cell of the present invention, after the joining step, a step of performing a vacuum treatment for the joined first and second layered structure bodies in a vacuum is additionally comprised, preferably.

By performing such the additional step of performing a vacuum treatment, joining between the first layered structure body and the second layered structure body can be made stronger.

Through the above-mentioned steps, the organic photovoltaic cell 10 is manufactured, in which, the first layered structure body 10A comprising: the first substrate 20A; the first electrode 32 provided on the first substrate 20A; the first electrical charge transport layer 42 provided on the first electrode 32; and the active layer 50 provided on the first electrical charge transport layer 42, and the second layered structure body 10B1 of the first embodiment comprising: the second substrate 20B; the second electrode 34 provided on the second substrate 20B; and the second electrical charge transport layer 44 provided on the second electrode 34, are joined.

An operation mechanism of a completed organic photovoltaic cell is described, here. Energy of incident light passed through a transparent or translucent electrode and entered into the active layer is absorbed by an electron-acceptor compound and/or an electron-donor compound, and generates an exciton in which an electron and a hole are bound. When the generated exciton moves and reaches the heterozygous interface at which the electron-acceptor compound and the electron-donor compound are joined, the electron and the hole are separated each other due to the differences in a HOMO energy and a LUMO energy of the respective compounds at the interface, and an electrical charge (electron and hole) that can move independently are generated. The generated electrical charges move to the respective electrodes (a cathode, an anode), and thereby an electric energy (current) can be extracted to the outside.

### Second Embodiment

A manufacturing method of an organic photovoltaic cell of the second embodiment is a method for manufacturing an organic photovoltaic cell provided with a pair of electrodes of a first electrode provided on a first substrate and a second electrode provided on a second substrate and an active layer placed by a pair of the electrodes, which comprises a step of forming a first electrical charge transport layer on the first electrode provided on the first substrate, a step of forming a first layered structure body by forming a first electrically conductive layer on the first electrical charge transport layer, a step of forming a second layered structure body by forming a second electrical charge transport layer on the second electrode provided on the second substrate and then forming a second electrically conductive layer on the second electrical charge transport layer, and a step of joining to form an active layer in which the first electrically conductive layer and the second electrically conductive layer are stacked after bringing the first electrically conductive layer and the second electrically conductive layer into contact with each other and joining them.

A manufacturing method of an organic photovoltaic cell of the second embodiment is described here in detail, referring to FIG. 1, FIG. 3, and FIG. 5. With regard to the similar structures to those of the first embodiment, same referring numerals are given, and a detailed description thereof may be omitted. With regard to the similar steps of the first embodiment, a detailed description for steps similar to those of the first embodiment may also be omitted.

FIG. 1 is a schematic sectional view (1) indicating a method for manufacturing an organic photovoltaic cell. FIG. 3 is a schematic sectional view (3) indicating a method for manufacturing an organic photovoltaic cell. FIG. 5 is a schematic sectional view (2) indicating a structure of an organic photovoltaic cell.

As illustrated in FIG. 1, firstly, a layered structure body 10A is prepared. For preparing the first layered structure body 10A, a first substrate 20A is prepared. The first substrate 20A is a plate-state substrate that has two primary surfaces facing each other. As the first substrate 20A, a substrate may be prepared, in which one of the primary surfaces of the first substrate 20A is pre-provided with a thin film made of an electrically conductive material capable of being a material for an electrode.

When the first substrate 20A is not provided with a thin film made of an electrically conductive material, a thin film made of an electrically conductive material is formed on one of the primary surfaces of the first substrate 20A by using arbitrarily an appropriate method such as evaporation. Next, the thin film of an electrically conductive material is patterned. The thin film of an electrically conductive material is patterned by using an arbitrary appropriate method such as a photolithography process and an etching process, and thereby a first electrode 32 is formed.

Next, a first electrical charge transport layer 42 is formed on the first electrode 32 provided on the first substrate 20A. The first electrical charge transport layer 42 is a hole transport layer when the first electrode 32 is an anode, and the first electrical charge transport layer 42 is an electron transport layer when the first electrode 32 is a cathode.

Next, a first electrically conductive layer 52 that covers the first electrical charge transport layer 42 is formed. When the first electrical charge transport layer 42 is an electron transport layer, the first electrically conductive layer 52 is an electron-acceptor layer comprising an n-type semiconductor material having re-type electrical conductivity. When the first electrical charge transport layer 42 is a hole transport layer, the first electrically conductive layer 52 is an electron-donor layer comprising a p-type semiconductor material having p-type electrical conductivity. With regard to an electron-acceptor compound that is a material for an electron acceptor layer and an electron donor compound that is a material for an electron donor layer, examples thereof are described as in the first embodiment.

The first electrical charge transport layer 42 and the first electrically conductive layer 52 may be formed by a film formation method using a coating fluid, i.e., a solution, as in the method of first embodiment.

Through the above-mentioned steps, the first layered structure body 10A comprising the first substrate 20A, the first electrode 32 provided on the first substrate 20A, the first electrical charge transport layer 42 provided on the first electrode 32, and the first electrically conductive layer 52 provided on the first electrical charge transport layer 42, is manufactured.

As illustrated in FIG. 3, a second layered structure body 10B2 is manufactured through steps different from the steps of manufacturing the first layered structure body 10A. First, a second electrode 34 is formed on one of primary surfaces of a second substrate 20B.

Next, a second electrical charge transport layer 44 is formed on the second substrate 20B provided with the second electrode 34 as in a manner similar to the step of forming the first electrical charge transport layer 42. The second electrical charge transport layer 44 is a hole transport layer when the second electrode 34 is an anode, and the second electrical charge transport layer 44 is an electron transport layer when the second electrode 34 is a cathode.

Subsequently, a second electrically conductive layer 54 that covers the second electrical charge transport layer 44 is formed in the same manner as the first electrically conductive layer 52 is formed. When the second electrical charge transport layer 44 is an electron transport layer, the second electrically conductive layer 54 is an electron-acceptor layer comprising an n-type semiconductor material having n-type electrical conductivity. When the second electrical charge transport layer 44 is a hole transport layer, the second electrically conductive layer 54 is an electron-donor layer comprising a p-type semiconductor material having p-type electrical conductivity. With respect to an electron-acceptor compound that is a material for an electron-acceptor layer and an electron-donor compound that is a material for an electron-donor layer, examples thereof are as described in the first embodiment.

Through the above-mentioned steps, a second layered structure body 10B2 of the second embodiment comprising the second substrate 20B, the second electrode 34 provided on the second substrate 20B, the second electrical charge transport layer 44 provided on the second electrode 34, and the second electrically conductive layer 54 provided on the second electrical charge transport layer 44, is manufactured.

As illustrated in FIG. 5, the manufactured first layered structure body 10A and the manufactured second layered structure body 10B2 are joined through the steps as described in the first embodiment. Thus, through the steps, the first electrically conductive layer 52 (an exposed layer at the opposite side to the first substrate) and the second electrically conductive layer 54 (an exposed layer at the opposite side to the second substrate) are joined. A layered structure of the first electrically conductive layer 52 and the second electrically conductive layer 54 corresponds to the active layer 50.

In the manufacturing method of the second embodiment, an organic photovoltaic cell becomes the pn-heterozigous (pn-heterojunction) type because the exposed layers are the first electrically conductive layer 52 and the second electrically conductive layer 54.

When a step of joining is performed in an atmosphere of solvent vapor, in which the surfaces of the exposed layers of both the first layered structure body 10A and the second layered structure body 10B2 are dissolved as described above, a bulk hetero layer (i layer) including mixed materials of the first electrically conductive layer 52 and the second electrically conductive layer 54 can be formed between the first layered structure body 10A and the second layered structure body 10B2 that are joined each other.

Through the above-mentioned steps, an organic photovoltaic cell 10 is manufactured, in which, the first layered structure body 10A comprising: the first substrate 20A; the first electrode 32 provided on the first substrate 20A; the first electrical charge transport layer 42 provided on the first electrode 32; and the first electrically conductive layer 52 provided on the first electrical charge transport layer 42, and the second layered structure body 10B2 of the second embodiment comprising: the second substrate 20B; the second electrode 34 provided on the second substrate 20B; the second electrical charge transport layer 44 provided on the second electrode 34; and the second electrically conductive layer 54 provided on the second electrical charge transport layer 44, are joined.

An organic photovoltaic cell that can be obtained by the manufacturing methods of the first embodiment and the second embodiment, as described in the above, does not require a sealant (an adhesive) to join a sealing substrate (a second substrate), and therefore a total thickness of a cell, especially a distance between the primary surface of the first substrate and the primary surface of the second substrate, which are facing each other, can be decreased. Specifically, the distance of a conventional structure between a primary surface of a first substrate and a primary surface of a second substrate that are facing each other was about 1 μm; on the other hand, the distance of a present invention can be made larger than 300 nm and smaller than 500 nm.

### <Organic Photovoltaic Cell>

An organic photovoltaic cell manufactured by a manufacturing method of the present invention is described, here. Some of examples of a layer structure, which can be adopted by an organic photovoltaic cell of the present invention, are as follows.

a) anode/active layer/cathode;
b) anode/hole transport layer/active layer/cathode;
c) anode/active layer/electron transport layer/cathode;
d) anode/hole transport layer/active layer/electron transport layer/cathode;
e) anode/electron-donor layer/electron-acceptor layer/cathode;
f) anode/hole transport layer/electron-donor layer/electron-acceptor layer/cathode;
g) anode/electron-donor layer/electron-acceptor layer/electron transport layer/cathode; and
h) anode/hole transport layer/electron-donor layer/electron-acceptor layer/electron transport layer/cathode;
(The symbol “/” indicates that layers at both sides of the symbol “/” are stacked adjacent to each other.)

The each layer abovementioned may be formed not only as a monolayer but also as a layered body having two or more layers. The proportion of an electron-acceptor compound in an organic photovoltaic cell having a bulk hetero active layer containing an electron-acceptor compound and an electron-donor compound is preferably 10 to 1000 parts by weight, more preferably 50 to 500 parts by weight, per 100 parts by weight of the electron-donor compound.

According to a method for manufacturing an organic photovoltaic cell of the present invention, an active layer and the like can be manufactured without being exposed to high temperature. Therefore, deterioration of electrical properties and loss of function due to a high-temperature treatment can be avoided.

In addition, because the two substrates are treated independently and then are joined, a manufacturing process can be made simple, and a combination of functional layers sandwiched by two substrates, such as electrodes an electrical charge transport layer and an active layer, can be changed easily. Therefore, according to a manufacturing process of the present invention, a wide variety of organic photovoltaic cells can be manufactured when needed, responding easily in such cases.

### <Application>

An organic photovoltaic cell manufactured by the manufacturing method of the present invention generates photopotential between electrodes by irradiating the first electrode and/or second electrode that is(are) transparent or translucent electrode(s) with light such as solar light, and thus it can operate as an organic thin film solar cell. Furthermore, by collecting and integrate the multiple organic thin film solar cells, it can be used as an organic thin film solar cell module.

In addition, in an organic photovoltaic cell manufactured by a manufacturing method of the present invention, under a condition with or without applying an electrical voltage between a first electrode and a second electrode, a photocurrent flows after a light passes through a transparent or translucent electrode and enters into the cell. Therefore, an organic photovoltaic cell manufactured by a manufacturing method of the present invention can operate as an organic light sensor. Furthermore, by collecting and integrate the multiple organic light sensors, it can be used as an organic image sensor.

### EXAMPLES

### Example 1

### (Preparation of First Layered Structure Body)

A glass substrate (the first substrate), on which a thin ITO film having a thickness of 150 nm was provided by sputtering on one of the primary surfaces thereof, was cleaned with acetone, followed by a UV-ozone cleaning treatment for 15 minutes using an ultraviolet ozone irradiation device equipped with a low pressure mercury vapor lamp (manufactured by TECHNOVISION, INC., TYPE: UV-312), and thereby the ITO electrode (the first electrode) having a clean surface was prepared. Next, TiO₂ (manufactured by Catalysts & Chemicals Industries Co., Ltd.; trade name, PALSOL HPW) was applied to on the surface of the ITO electrode by spin coating, and thereby a TiO₂ layer (the first electrical charge transport layer) was formed. Then, the obtained TiO₂ layer was dried at 150° C. for 40 minutes in the atmosphere. An electron-donor compound of poly(3-hexylthiophene)(P3HT)(manufactured by Merck; trade name, lisicon SP001, lot. EF431002) and an electron-acceptor compound of PCBM (manufactured by Frontier Carbon Corporation; trade name, E100, lot. 7B0168-A) as the fullerene derivative were added into an o-dichlorobenzene solvent so that P3HT is 1.5 wt % and PCBM is 2 wt %, followed by stirring at 70° C. for 2 hours and by filtration through a filter having a pore size of 0.2 μm, and thereby a coating fluid was prepared. On the TiO₂ layer, the coating fluid was applied by spin coating, followed by a heat treatment at 150° C. for 3 minutes in an atmosphere of nitrogen gas, and thereby an active layer film was formed. After the heat treatment, a film thickness of the active layer was about 100 nm.

### (Preparation of Second Layered Structure Body)

After a glass substrate (the second substrate) was cleaned with acetone, a UV-ozone cleaning treatment was performed for 15 minutes using an ultraviolet ozone irradiation device equipped with a low pressure mercury vapor lamp. Next, after Ag paste (manufactured by MITSUBOSHI BELTING LTD.; trade name, MDot-SLP) was applied to the glass substrate by screen printing, followed by a heat treatment at 200° C. for 30 minutes in the atmosphere, to form a second electrode, and thereby a second layered structure body was formed. After the heat treatment, a thickness of the Ag layer was 5 μm. Next, PEDOT layer (manufactured by H. C. Starck GmbH; trade name, Baytron P AI4083, lot. HCD0701019) was applied to the Ag layer by spin coating, and thereby a PEDOT layer (the second electrical charge transport layer) was formed. The obtained was dried at 150° C. for 30 minutes in the atmosphere.

### (Preparation of Organic Photovoltaic Cell)

The first substrate provided with the first electrode, the electrical charge transport layer and the active layer (the first layered structure body); and the second substrate provided with the second electrode and the second electrode (the second layered structure body) were superimposed so that the active layer and the second electrical charge transport layer contact each other, at 25° C. (the ordinary temperature) in a sealed container filled with a chloroform-saturated vapor pressure, and kept under a pressurization state for 30 minutes to join them. The obtained organic photovoltaic cell had a 2 mm×2 mm square shape.

### <Evaluation>

### (Measurement of Photovoltaic Conversion Efficiency)

The organic photovoltaic cell manufactured in Example 1 was evaluated for photovoltaic conversion efficiency by measuring an electrical current and an electrical voltage, using a solar simulator (manufactured by YAMASHITA DENSO; trade name, YSS-80) to irradiate with light having an irradiance of 100 mW/cm² passed through an AM1.5G filter, and as the result, a power generation was observed.

### INDUSTRIAL APPLICABILITY

The present invention is useful for manufacturing an organic photovoltaic cell.

1. A method for manufacturing an organic photovoltaic cell comprising a first substrate, a second substrate, a pair of electrodes of a first electrode provided on the first substrate and a second electrode provided on the second substrate, and an active layer placed between the pair of electrodes, the manufacturing method comprising the steps of:
forming a first electrical charge transport layer on the first electrode provided on the first substrate;
forming a first layered structure body by forming the active layer on the first electrical charge transport layer;
forming a second layered structure body by forming a second electrical charge transport layer on the second electrode provided on the second substrate; and
joining the first layered structure body and the second layered structure body by bringing the active layer provided on the first layered structure body and the second electrical charge transport layer provided on the second layered structure body into contact with each other.

2. A method for manufacturing an organic photovoltaic cell comprising a first substrate, a second substrate, a pair of electrodes of a first electrode provided on the first substrate and a second electrode provided on the second substrate, and an active layer placed between the pair of electrodes, the manufacturing method comprising the steps of:
forming a first electrical charge transport layer on the first electrode provided on the first substrate;
forming a first layered structure body by forming a first electrically conductive layer on the first electrical charge transport layer;
forming a second layered structure body, by forming a second electrical charge transport layer on the second electrode provided on the second substrate and forming a second electrically conductive layer on the second electrical charge transport layer; and
joining the first electrically conductive layer and the second electrically conductive layer, by bringing the first electrically conductive layer and the second electrically conductive layer into contact with each other and joining them to form the active layer in which the first electrically conductive layer and the second electrically conductive layer are stacked.

3. The method for manufacturing an organic photovoltaic cell according to claim 1, wherein, in the joining step, either one or both of the first substrate and the second substrate is pressurized.

4. The method for manufacturing an organic photovoltaic cell according to claim 1, wherein the joining step is performed under a temperature higher than an ordinary temperature.

5. The method for manufacturing an organic photovoltaic cell according to claim 4, wherein the joining step is performed under a temperature higher than 40° C. and lower than 100° C.

6. The method for manufacturing an organic photovoltaic cell according to claim 1, wherein the joining step is performed in an atmosphere of solvent vapor that dissolves a surface of either one or both of: an exposed layer that is included in the first layered structure body and exists at an opposite side to the first substrate; and an exposed layer that is included in the second layered structure body and exists at an opposite side to the second substrate.

7. The method for manufacturing an organic photovoltaic cell according to claim 6, wherein an aromatic hydrocarbon vapor or an aliphatic hydrocarbon vapor is used as the solvent vapor.

8. The method for manufacturing an organic photovoltaic cell according to claim 6, wherein water vapor or an alcohol vapor is used as the solvent vapor.

9. The method for manufacturing an organic photovoltaic cell according to claim 1, after the joining step, further comprising a step of performing a vacuum treatment in a vacuum to the first layered structure body and the second layered structure body that are joined to each other.

10. The method for manufacturing an organic photovoltaic cell according to claim 6, wherein, in the joining step, either one or both of the exposed layer that is included in the first layered structure body and exists at the opposite side to the first substrate and the exposed layer that is included in the second layered structure body and exists at the opposite side to the second substrate is a layer comprising an organic compound.

11. The method for manufacturing an organic photovoltaic cell according to claim 6, wherein, in the joining step, either one or both of the exposed layer that is included in the first layered structure body and exists the opposite side to the first substrate and the exposed layer that is included in the second layered structure body and exists at the opposite side to the second substrate is a layer comprising an inorganic compound.

12. An organic photovoltaic cell manufactured by the manufacturing method according to claim 1.

13. The organic photovoltaic cell according to claim 12, wherein a distance between a primary surface of the first substrate and a primary surface of the second substrate, which face each other, is larger than 300 nm and smaller than 500 nm.

14. The organic photovoltaic cell according to claim 12, wherein the substrate of either one or both of the first substrate and the second substrate is an inorganic compound film.

15. The organic photovoltaic cell according to claim 12, wherein the substrate of either one or both of the first substrate and the second substrate is an organic compound film.

16. The organic photovoltaic cell according to claim 14, wherein the inorganic compound film is made of a metal or an alloy.

17. The organic photovoltaic cell according to claim 15, wherein the organic compound film further comprises a barrier layer.
